(19) United States
(12) Patent Application Publication
(10) Pub. No.: US 2015/0262905 A1
(43) Pub. Date: Sep. 17, 2015

(54) GROUNDING SYSTEM FOR COOLING OF ELECTRONIC DEVICES USING DIELECTRIC FLUIDS

(71) Applicant: Alcatel-Lucent, USA Inc., Murray Hill, NJ (US)

(72) Inventor: Todd R. Salamon, Murray Hill, NJ (US)

(73) Assignee: Alcatel-Lucent, USA Inc., Murray Hill, NJ (US)

(21) Appl. No.: 14/212,007

(22) Filed: Mar. 14, 2014

(51) Int. Cl. H01L 23/367; H01L 23/473; H01L 21/48

(52) U.S. Cl. CPC H01L 23/3675; H01L 21/4803; H01L 23/473

(57) ABSTRACT

An apparatus comprising an integrated circuit. The integrated circuit comprises a substrate having a planar surface, a plurality of active electronic and/or optical devices located over the planar surface in the integrated circuit, and, a planar channel having a hollow interior and being located between the active electronic and/or optical devices, and the substrate. A portion of a segment of the planar channel is formed of metal or graphene.

### GOVERNMENT LICENSE RIGHTS

The U.S. Government has a paid up license related to the subject matter of this application and may have the right in limited circumstances to require the patent owner to license others on reasonable terms as provided for by the terms of Contract No. HR0011-13-2-0009 awarded by DARPA under Sub-award No. 5710003438.

### TECHNICAL FIELD

The invention relates, in general, to a cooling apparatus and, more specifically, to an apparatus for cooling electronic devices, and to a method of manufacturing the apparatus.

### BACKGROUND

This section introduces aspects that may help facilitate a better understanding of the inventions. Accordingly, the statements of this section are to be read in this light and are not to be understood as admissions about what is prior art or what is not prior art.

Active electronic, optical or other device components can generate heat, and the heat is dissipated so that the components can operate at a desired temperature and/or so that the components will continue to operate over a desired lifetime. An inability to adequately dissipate the internally generated heat can limit capacities and/or functionalities of such components and/or can result in the premature failure of such components. For example, thermal dissipation limitations have impacted computer chips and their design and architecture.

### SUMMARY

One embodiment is an apparatus. The apparatus comprises an integrated circuit, the integrated circuit comprises a substrate having a planar surface, a plurality of active electronic and/or optical devices located over the planar surface in the integrated circuit, and, a planar channel having a hollow interior and being located between the active electronic and/or optical devices, and the substrate. A portion of a segment of the planar channel is formed of metal or graphene.

In any such embodiments, the portion can form a top surface or a bottom surface of the segment of the planar channel.

In any such embodiments, the portion can form between 25 percent and 75 percent of a surface of a cross section of the segment of the planar channel.

In any such embodiments, the integrated circuit can include a second substrate and the interior of the planar channel is located between the substrates.

In any such embodiments, the portion can be connected to a ground body of the integrated circuit.

In any such embodiments, can further comprise a pump connected to move a liquid through the channel.

In any such embodiments, can further comprise a heat exchanger configured to receive fluid from the channel and being located external to the integrated circuit.

In any such embodiments, can further comprise a pump connected to move the fluid through the channel and from the channel to the heat exchanger.

Another embodiment is method that comprises forming an integrated circuit. Forming the integrated circuit includes providing a substrate having a planar surface, forming a plurality of active electronic and/or optical devices located over the planar surface in the integrated circuit, and, forming a planar channel having a hollow interior and being located between the active electronic and/or optical devices, and the substrate, wherein a portion of a segment the planar channel is formed of metal or graphene.

In any such embodiments, forming the integrated circuit can further include providing a second substrate 107a and the interior of the planar channel is located between the substrates.

In any such embodiments, forming the integrated circuit can further include forming a metal and/or doped semiconductor path connecting the portion to a surface of the substrate.

In any such embodiments, forming the integrated circuit can further include forming a ground body and connecting the portion the ground body.

Any such embodiments can further include connecting a pump configured to move a liquid through the channel.

Any such embodiments can further include providing a heat exchanger configured to receive fluid from the channel and being located external to the integrated circuit.

Some such embodiments can further include connecting a pump to move the fluid through the channel and from the channel to the heat exchanger.

Another embodiment is an apparatus comprising an integrated circuit having a substrate with at least one heat-generating component thereon, a channel located adjacent to the substrate and in a vicinity of the at least one of the heat-generating component, wherein the channel is configured to carry a dielectric fluid there-through; and a grounding system. The grounding system includes an electrically conductive layer located on at least one wall of the channel and configured to electrically connect to the dielectric fluid in the channel. The grounding system includes a ground body adjacent to the substrate, and one or more ground-path structures located in the substrate and electrically connecting the electrically conductive layer to the ground body.

In some such embodiments, at least a segment of the electrically conductive layer, located on the at least one wall of the channel and configured to electrically connect to the dielectric fluid in the channel, is formed of graphene. In some such embodiments, at least a portion of the ground-path structure includes a structure that traverses the channel and contacts the he dielectric fluid in the channel. In some such embodiments, the structure traversing the channel is a via structure that passes through the substrate and contacts the ground body.

### BRIEF DESCRIPTION OF THE DRAWINGS

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1A presents a side cross-sectional view of an example apparatus of the present disclosure;

FIG. 1B presents a side cross-sectional view of an example apparatus of the present disclosure;

FIG. 2 presents a side cross-sectional view of an example apparatus of the present disclosure;

FIG. 3A presents a side cross-sectional view of an example apparatus of the present disclosure having a stack of two or more substrates;

FIG. 3B presents a side cross-sectional view of another example apparatus of the present disclosure having a stack of two or more substrates;

FIG. 4 presents a flow diagram of an example method of manufacturing an apparatus of the disclosure, such as any of the example apparatuses described in the context of FIGS. 1-3; and

FIG. 5 presents a flow diagram of an example method of manufacturing an apparatus of the disclosure, such as any of the example apparatuses described in the context of FIGS. 1-3.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION

The description and drawings merely illustrate the principles of the inventions. It will thus be appreciated that those skilled in the art will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

Embodiments of the disclosure can facilitate the use of inter- or intra-component embedded cooling systems, where a dielectric cooling fluid is circulated within or in a vicinity of one or more heat-generating device components. Providing an electrical grounding system connected to a channel circulating the dielectric fluid helps prevent the accumulation of an electrical charge (e.g., tribological charging), and thereby avoid detrimental effects associated with charge accumulation.

The term “dielectric fluid,” as used herein, refers to a fluid having electrical insulating properties and cooling properties, e.g., a dielectric liquid. Example dielectric fluids include, but are not limited to, fire-resistant and/or non-flammable fluids such as pure water (e.g., deionized or distilled liquid water) or fluorine containing refrigerants (e.g., R134a, R22, FC77 refrigerants). Non-limiting example dielectric fluids that are not fire-resistance and are flammable include hydrocarbons such as n-butane or n-pentane. In some embodiments, the dielectric fluid has a dielectric constant or relative permittivity of at least about 50, and, in some embodiments, at least about 100. In some embodiments, the dielectric fluid has a dielectric constant or relative permittivity of at least about 50, and in some embodiments, at least about 100 (at standard condition of 1 atmosphere and 20° C.). In some embodiments, the dielectric fluid has an electrical conductivity of less than about 100E-6 S/m and in some cases less than about 5×10⁻⁶ S/m (at standard conditions). In some embodiments, to facilitate heat absorption a dielectric fluid is selected that changes phase from liquid to vapor when absorbing heat from the heat-generating component. That is the dielectric fluid is a two-phase dielectric fluid. In some embodiments, the dielectric fluid is a single (e.g., liquid) phase dielectric fluid, where the sensible heat rise of the liquid absorbs heat from the heat-generating component. In some embodiments, the dielectric fluid heat absorption occurs via both the sensible heat rise (single phase) and the liquid-to-vapor phase change (two-phase) when absorbing heat from the heat-generating component.

Tribological charging refers to the formation of a static electrical charge when a dielectric fluid flows within an electrically-insulating channel at a sufficiently high mass flow rate. One skilled in the pertinent arts would be familiar with conditions where a dielectric fluid can undergo static electric charging (e.g., tribological charging). In some embodiments, the static tribological charge can accumulate on walls of a channel until it reaches a level whereby it can overcome the electrical resistance to ground. The sudden discharge of such a static electric charge can cause damage to the device component or cause the device component to malfunction.

As part of the present disclosure, it was recognized that locating grounding pathways of an electrical grounding system in the vicinity of heat-generating device components being cooled by a dielectric fluid can beneficially reduce the formation of local tribological static charges. It was also recognized that providing a grounding path system in the vicinity of device components helps to mitigate the accumulation of relatively small static electric charges that may not be sufficient to damage the components, but nevertheless may cause the components to malfunction.

For example, for a large resistance to ground, significant levels of charge can develop (e.g., greater than about 10 kV and in some example), and, sudden discharge can lead to the creation of pin hole defects in the channel walls as a discharge arcs through the channel walls to ground. For example, for device components of integrated circuits, even a small local build-up of a tribological static charge (e.g., less than 1 kV or less than 100 V, or less than 10 V, or less than 1 V in some embodiments) may be sufficient to cause electric arcing over the short distances of conductors carrying electrical signals in the circuit and may this create physical defects or malfunctions in device components. The presence of a small local static charge may be sufficient to alter the normal function of device components. For instance, the presence of a static charge in the vicinity of a transistor component of an integrated circuit chip may alter the electric potential between a source, drain or gate of the transistor, and thus may alter the operation of the transistor. Or, the presence of a static charge could alter the information traveling through an electrical interconnection between transistors or between transistors and memory components (e.g., SRAM or DRAM components) of a device. Or, the presence of a static charge could alter the impedance along the interconnection between device components.

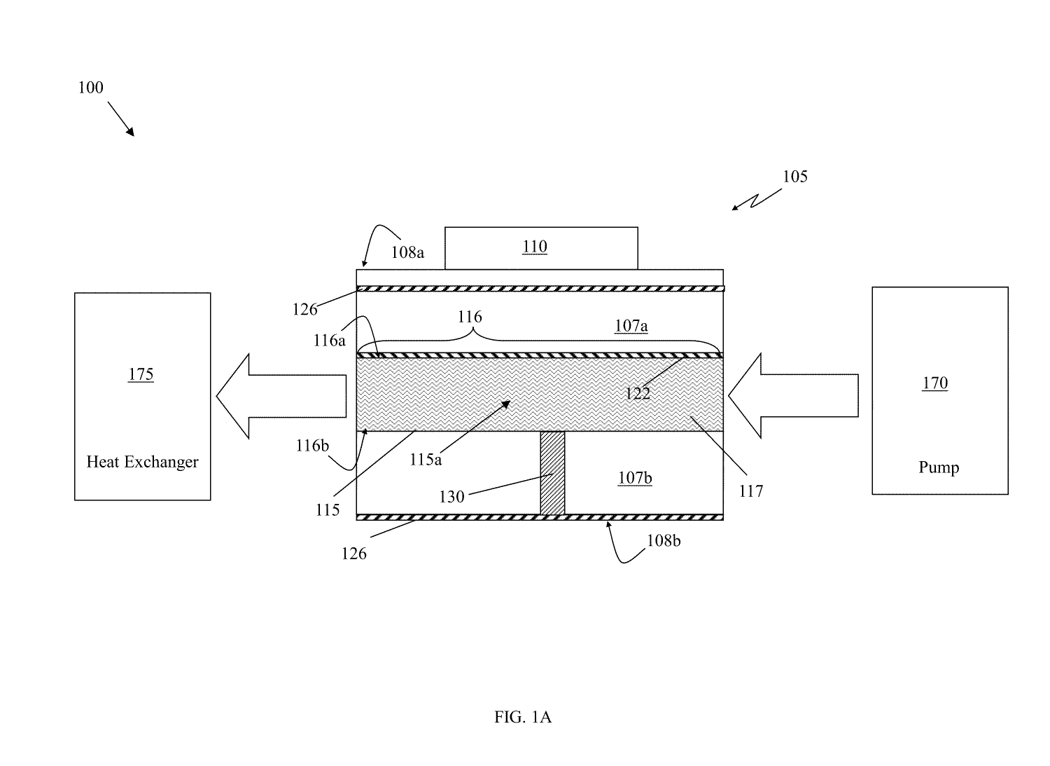

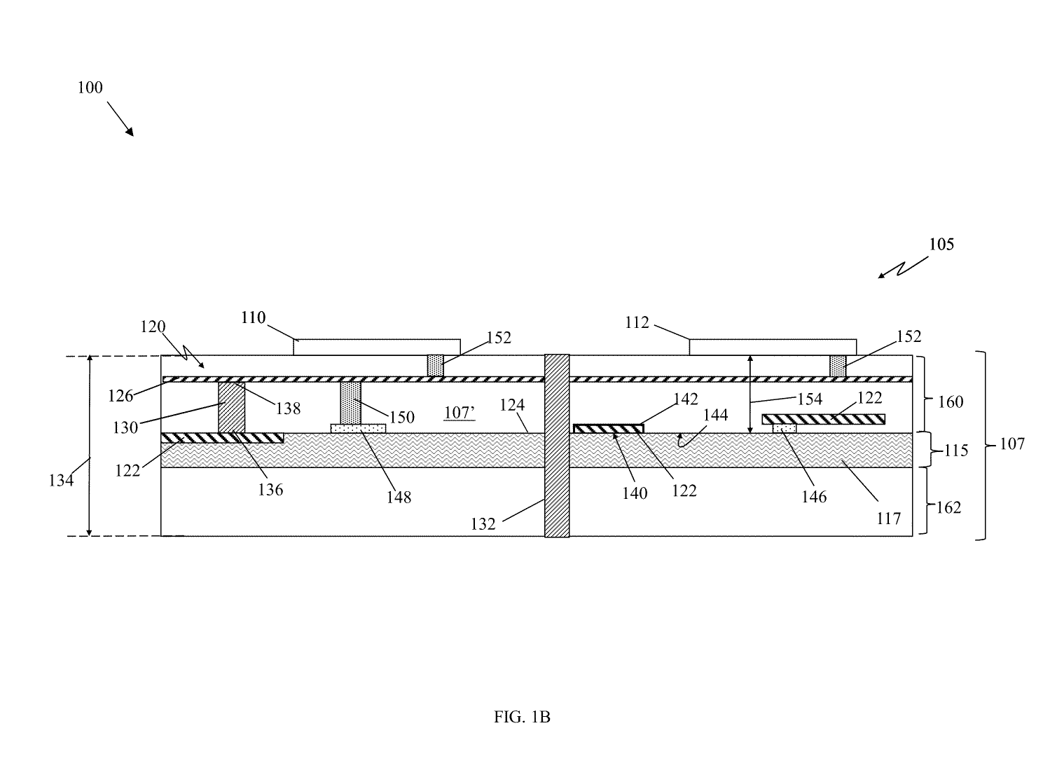

One embodiment of the disclosure is an apparatus. FIG. 1A presents a side cross-sectional view of an example apparatus 100 of the present disclosure.

As illustrated the apparatus 100, comprises an integrated circuit 105. The integrated circuit 105 comprises a substrate 107a having a planar surface 108a and a plurality of active electronic and/or optical devices 110 located over the planar surface 108a in the integrated circuit 105. The integrated circuit 105 also comprises a planar channel 115 having a hollow interior 115a and being located between the active electronic and/or optical devices 110, and the substrate 107a. A portion 122 of a segment 116 of the planar channel 115 is formed of metal or graphene.

In some embodiments, as illustrated in FIG. 1A, the portion 122 forms a top surface (e.g., a surface 116a closest to the devices 110) of the segment 116 of the planar channel 115. Additionally or alternatively, in some embodiments, the portion 122 forms a bottom surface (e.g., a surface 116b farthest from the devices 110) of the segment 116 of the planar channel 115.

It is thought that, at least in some embodiments, accumulated charges will have difficulty in migrating through a dielectric fluid 117 in the channel 115 and therefore surface charges preferably pass very close to the graphene or metal portion 122 to be charge-dissipated. Therefore, in some embodiments, to facilitate the removal of charge, it is preferred that a large percentage of the segment 116 be composed of the graphene or metal portion 122. In some embodiments, for example, the portion 122 forms between 25 percent and 75 percent of a surface, e.g., surface 116a or 116b, of a cross section of the segment 116 of the planar channel 115. In some embodiments as illustrated in FIG. 1A, an entire surface 116a of the channel segment 116 can be composed of the graphene or metal portion 122.

As further illustrated in FIG. 1A, in some embodiments, the integrated circuit 105 includes a second substrate 107b and the interior 116 of the planar channel 115 is located between the substrates 107a, 107b.

As further illustrated in FIG. 1A, in some embodiments of the integrated circuit 105, the portion 122 is connected by a metal and/or doped semiconductor path 130 to a surface of the substrate (e.g., surface 108b of the substrate 107b).

To facilitate charge dissipation, the portion 122 can be connected to a ground body 126 of the integrated circuit 105. For instance, in some embodiments, the metal and/or doped semiconductor path 130 can connect the portion 122 to the ground body 126. In some embodiments, the ground body 126 can be located between the active devices 110 and the channel 115 and may act to electrically shield the active devices 110 against such arcing. In other embodiments, the ground body 126 can be located on a side of the substrate 107b that is opposite the side of the substrate 107a that the active devices 110 are located on, to avoid having dissipating static charge accumulating near regions of the circuit 105, where such charge could interfere with the operation of the devices 110. In some embodiments, to further facilitate charge dissipation, the portion 122 can be connected to a ground body 126 or multiple ground bodies at regular intervals, e.g., via multiple paths 130.

Using similar reference numbers to depict similar features, FIGS. 1B-3B illustrate further details of these various and other aspects of embodiments of the apparatus 100. FIG. 1B presents a side cross-sectional view of another example apparatus 100 of the present disclosure. The apparatus 100 comprises an integrated circuit 105 having a substrate 107 with at least one active device heat-generating component thereon (e.g., at least one of active device components 110, 112 configured to generate heat during operation). The apparatus 100 also comprises a channel 115 located adjacent to the substrate 107. The channel 115 is located in a vicinity of the at least one of the heat-generating component 110, 112. The channel 115 is configured to carry a dielectric fluid 117 there-through.

Some embodiments of the apparatus 100 such as depicted in FIG. 1B can comprise a grounding system 120. The system 120 includes an electrical conductive layer 122 (e.g., a layer composed of metal, graphene or carbon nanotubes) located on at least one wall 124 of the channel 115 (e.g., interior channel wall) and configured to electrically connect to the dielectric fluid 117 in the channel 115, i.e., makes physical contact with some of the fluid 117 in the channel 115. The system 120 also includes a ground body 126 (e.g., a ground plane in some embodiments) adjacent to the substrate 110. The system 120 also includes one or more ground-path structures (e.g., one or more path structures 130, 132) located in the substrate 110 and electrically connecting the electrically conductive layer 122 to the ground body 126. In some cases as illustrated in FIG. 1B a ground-path structure (e.g., structure 132) may traverse the channel 115 and therefore partially block the flow of the dielectric fluid 117 through the channel 115. One skilled in the pertinent art would understand how to adjust the sizes of the channel 115 and structure 132 to permit adequate flow of dielectric fluid 117 through the channel 115 despite the presence of ground-path structures 130 on the walls 124 of the channel 115 or even structures 132 traversing the channel 115. One skilled in the pertinent art would be familiar with different ways the ground body 126 could be connected to an electrical ground of the apparatus 100.

The term integrated circuit as used herein refers to any physically integrated device having a plurality of active electronic and/or active optical components, e.g., transistor(s), light-emitting diode(s), optical amplifier(s), and/or laser(s) integrated onto a solid substrate. For example, the integrated circuit 105 can include a portion of a single integrated circuit die or chip having electronic or optical components 110, 112 capable of generating heat during operation. One of ordinary skill in the pertinent art would understand that an active device is a device that is capable of adjustably controlling the flow or charge carriers and requiring a separate power source (e.g., a non-signal power source) to perform its function. Non-limiting example electrical active devices include field effect transistor devices such as NMOS, PMOS, CMOS transistors; memory devices such as SRAM, DRAM, EEPROM. One of ordinary skill would understand how active and passive device components can be fabricated on or in a semiconductor substrate or other solid substrate 107 to form an integrated circuit. In some embodiments, for example, the integrated circuit 105 can include an assembly of such electronic integrated circuits. In some embodiments, for example, the integrated circuit 105 can include one or more photonic integrated circuits having heat-generating components 110, 112 such as one or more lasers, thermo-optic and/or electro-optic phase shifters, optical amplifiers or other components familiar to those skilled in the relevant arts. In some embodiments, for example, the integrated circuit 105 can include an assembly of both active electronic and active photonic components on the same integrated circuit (e.g., an optoelectronic circuit). In still other embodiments, the integrated circuit can be or include a radio frequency monolithic microwave integrated circuit.

In some embodiments, at least one of the ground-path structures (e.g., structure 130) can be or include a via that, for example, passes through at least a portion of a thickness 134 of the substrate 110. For instance, in some embodiments, the via 130 can be or include a copper or tungsten plug and surrounding barrier layer as familiar to those skilled in the art. In some embodiments, at least one of the ground-path structures (e.g., structure 132) can be or include a through-substrate fully or partially metal-filled via. In some embodiments, the through-substrate via 132 can span the entire thickness 134 of the substrate 107, or in some embodiments, a plurality of substrates. In some such embodiments, a portion of the through-substrate via 132 may be open into or pass through the channel 115 and directly contact the dielectric fluid 117 to thereby provide a further a low resistance ground path, e.g., metal path, for the discharge of electrical charges carried on the moving dielectric fluid.

In some embodiments, to facilitate the electrical connection and reduce the potential for electric charge build-up, the ground-path structure 130, 132, can directly contact both the electrically conductive layer 122 and the ground body 126. For instance, in some embodiments, one end 136 of the ground path structure 130 can contact the electrically conductive layer 122 and the opposite end 138 of the structure 130 can contact the ground body 126.

In some embodiments, to facilitate the electrical connection and reduce the potential for electric charge build-up, at least a portion (e.g., side 140 of conductive layer 122 in FIG. 1B) of the electrically conductive layer 122 can contact the dielectric fluid 117.

In some embodiments, to facilitate a low resistance grounding path with high electrical conductivity, at least one electrically conductive layer 122 can be a metal layer, for example copper, tungsten, silver, a metal alloy or other conductor (e.g., doped or heavily doped semiconductor, graphene, or a doped carbon nanotube dispersion) familiar to those skilled in the pertinent arts.

In some embodiments, to improve the flow of the dielectric fluid 117 flowing through the channel 115, the electrically conductive layer 122 can be embedded in a wall (e.g., wall 124) of the channel. For instance, in some embodiments, a conductive layer 122 can be formed in a trench 142 of a channel wall (e.g., wall 124). In some embodiments, the side 140 of layer 122 faces the fluid 117 and is flush with adjacent other surfaces 144 of the wall 122 thereby reducing the flow resistance of the dielectric fluid 117 flowing through the channel 115 as compared to embodiments without such a flush construction of different portions of the surfaces of the channel 115.

In some embodiments, the conductive layer 122 can be buried in the channel wall 124 so as to not directly contact the dielectric fluid 117. In some such embodiments, a doped semiconductor portion 146 (e.g., an N-type or P-type doped semiconductor portion) of the substrate 107 can electrically connect at least one of the layers 122 (e.g., a metal, doped or heavily doped semiconductor, graphene, or a dispersion of doped carbon nanotubes) to the dielectric fluid 117. Then, the doped semiconductor portion 146 of the substrate 107 can be located between the electrically conductive layer 122 and the dielectric fluid 117 and contacts both of the layer 122 and the moving fluid 117 during operation.

In some embodiments, to facilitate a low resistance grounding path, at least one electrically conductive layer 122 can be or include a portion 148 of the substrate 107 that is doped semiconductor (e.g., doped with N-type or P-type dopants). In some embodiments, forming electrically conductive layers 122 as a doped portion of the substrate 107 can facilitate fabrication of the grounding system 120 by avoiding the need to form, e.g., a metal conductive layer 122 on or in the channel wall 124. Additionally, in some embodiments, the doped portion 148 of the substrate 107 can be flush with the other portions 144 and thereby facilitate the flow of the fluid 117 through the channel 115. However, doped semiconductor may have decreased thermal conductivity with respect to some metals and metal alloys, and therefore a metal conductive layer 122 may be preferred in some embodiments. Alternatively charge-dopant types may be selected to increase electrical conductivity of the layer 122 without decreasing thermal conductivity.

In some embodiments, at least one of the low resistance ground-path structures (e.g., structure 150) can be or include a portion 148 of the substrate 107 that is doped, for example, with N-type (e.g., silicon doped with P or As atoms) or P-type (e.g., silicon doped with B atoms) dopants. In some embodiments, forming the ground-path structures 150 as heavily doped semiconductor portions of the substrate 107 can facilitate fabrication of the grounding system 120 by avoiding the need to form, e.g., a metal ground-path structure.

As illustrated in FIG. 1B, in some embodiments, the ground body 126 (e.g., a metal, doped or heavily doped semiconductor, graphene, or doped carbon nanotube dispersion can be located within the substrate 107 (e.g., on an interior substrate layer 107′) and located in between the channel 115 and the integrated circuit 105. In some such embodiments, the ground-path structure (e.g., structure 130 or 150) can at least span the portion of the substrate 107 located in between the ground body 126 and the electrically conductive layer 122.

In some embodiments, as illustrated in FIG. 1B, the integrated circuit 105, and in some embodiment, at least one heat-generating active device component (e.g., at least one of 110, 112) is electrically connected to the ground body 126 (e.g., by a via 151 connection).

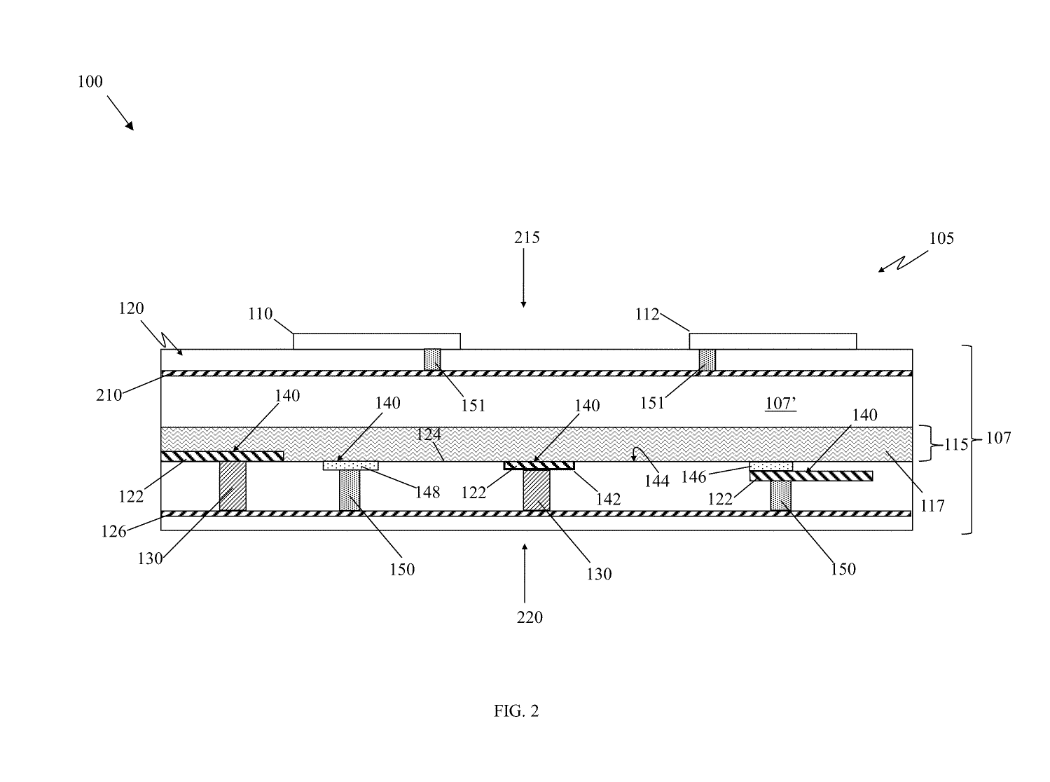

In some embodiments, as illustrated in FIG. 2, the apparatus 100 can further include a second ground body 210 (e.g., a second ground plane in some embodiments). The integrated circuit 105 can be electrically connected the second ground body 210 (e.g., by via 151 connections). One skilled in the pertinent art would understand how the second ground body 210 could be connected to an electrical ground. In some such embodiments, the ground body 126 (e.g., a first ground body) can be more distal from the integrated circuit 105 than the channel 115. For instance, in some embodiments, the first ground body 126 can be used as part of the static charge ground path of the grounding system 120 which can separate from the ground body 210 used to ground the integrated circuit components 110, 112 or the circuit 105 in general. For instance, in some embodiments, the second ground body 210 can be located at or near a top-side 215 of the substrate 107 (e.g., a side that houses the integrated circuit 105) and the ground body 126 is located at or near a bottom side 220 of the substrate 107 that is opposite to the top side 215. In some embodiments, the location of the first ground body 126 can be less distal from the integrated circuit 105 than the channel 115. For example, the ground body 126 could be located directly below the second ground body 210 and above the channel 115. One skilled in the pertinent art would appreciate that there could be other relative arrangements of the first and second ground bodies 126, 210, or that additional ground bodies could be located on or in the substrate 107.

In some embodiments, the substrate 107 can be or include silicon, silicon-on-insulator, silicon carbide, diamond or other semiconductor or ceramic material layers. In some embodiments, the heat generating active device components 110, 112 can each be or include one or more integrated circuits. For example, in some embodiments, the heat generating active device components 110, 112 configured as one or more integrated circuits can include electronic integrated circuit 110, photonic integrated circuit 112, or hybrid combinations of such circuits on a common substrate 107. Embodiments of the heat generating active device components 110, 112, can include active electronic and/or optical components, or passive components which internally generate heat. For instance, the integrated circuit 105 include heat generating active device components 110, 112 each configured as a plurality of integrated circuit chips mounted on a circuit board substrate 107, and such integrated circuit chips can be interconnected in a parallel array to form a multicore central processing unit.

Returning to FIG. 1B, in some embodiments, for example, to facilitate efficient heat transfer, the channel 115 of the apparatus 100 is in the vicinity of the one heat-generating active device components. In some embodiment, for example, a distance 154 separating an active device component 110, 112 and the equals about 500 microns or less. In some embodiments where there is a large temperature drop over substrate 107, the distance 154 is preferably about 200 microns or less, and in some embodiments, about 100 microns or less. In some embodiments, the distance 154 has a value in a range from 100 to 50 microns, or in some embodiments 50 to 20 microns.

As illustrated in FIG. 1B, in some embodiments, for example, to facilitate a compact vertical profile, the one channel wall 124 that the electrically conductive layer 122 located on is closer to the integrated circuit 105 than other walls (e.g., opposite wall 156) of the channel 115.

In some embodiments, to reduce possible interference with heat transfer from the heat generating active device components 110, 112 to the fluid 117, the side 140 of the electrically conductive layer 122 facing the fluid 117 occupies is about 10 percent or less, and in some embodiments, about 1 percent or less, of a total surface area of the wall 124 of the channel 115 that the layer 122 is located on. In some embodiments as illustrated in FIG. 1B, there can be a plurality of conductive layers 122 along the length of the one wall 124, and, the total of surface areas of the layers 122 (e.g., the total area of the sides 140) occupies about 10 percent or less, and in some embodiments about 1 percent or less, of a total surface area of the wall 124 of the channel 115.

As illustrated in FIG. 2, in some embodiments, to reduce interfering with heat transfer from the heat generating components 110, 112 to the fluid 117, the electrically conductive layer 122 (or layers 122) can be located on one channel wall 156 that is farther away from the integrated circuit 105 than other walls (e.g., of the channel wall 124.

In still other embodiments, to facilitate providing multiple paths to ground along the channel 115, there can be a plurality of conductive layers 122 each located on multiple different walls 124, 156 of the channel 115, with each of the layers 122 being connected to one of the ground-path structures (e.g., at least one of structures 130, 132).

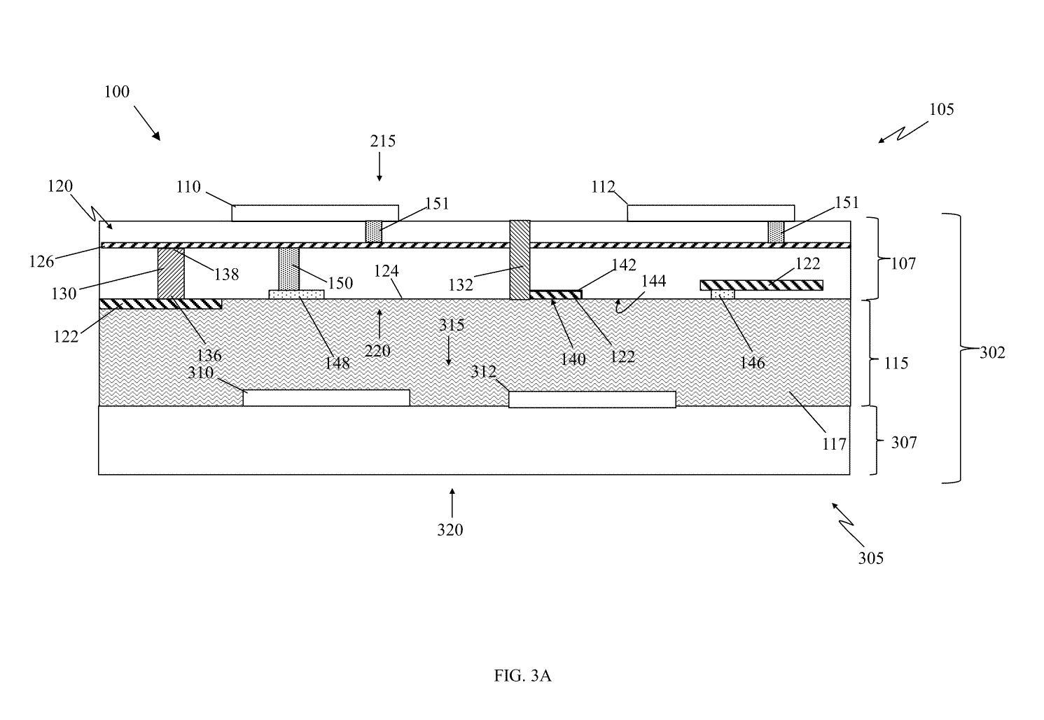

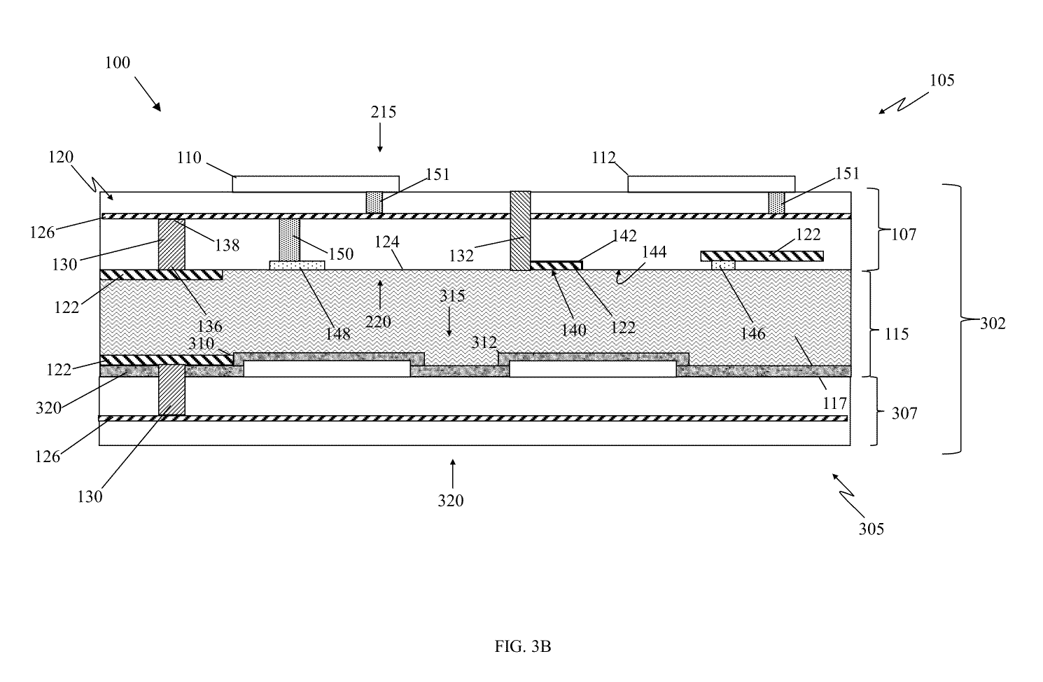

FIG. 3A presents a side cross-sectional view of another example apparatus 100 having a stack 302 of two or more substrates. In some embodiments, the apparatus 100 can include a second integrated circuit 305 located on a second substrate. As a n example, the second integrated circuit 305 can include second heat-generating active device components 310, 312 on the second substrate 307, similar to that described above in the context of FIG. 1B for a first integrated circuit 105. In some embodiments, the substrate 107 and second substrate 307 can be stacked together, and, the channel 115 can be located between the substrate 107 and the second substrate 307. In some embodiments, to facilitate heat transfer to the fluid 117, one of the heat-generating active device components (e.g., components 110, 112) or second heat-generating active device components (e.g., components 310, 312 in FIG. 3A) can be located on a side of the substrate or the second substrate (e.g., a top side 315 of the second substrate 307 in FIG. 3A) that faces the channel 115. In other embodiments, the heat-generating active device components 110, 112, located on top side 215 of the first integrated circuit, and, the second heat-generating active device components 310, 312, located on top side 315 of the second integrated circuit 307, can both face the channel 115. In other embodiments, component-free sides 220, 320 of integrated circuits 105, 305 can both face the channel 115.

FIG. 3B presents a side cross-sectional view of another example apparatus of the present disclosure having a stack 302 of two or more substrates 107, 307. The embodiment in FIG. 3B is similar to the embodiment depicted in FIG. 3A, except that one or more electrically insulating layers (e.g., layer 320) covers the second heat-generating components 310, 312. Covering the second heat-generating components 310, 312 with the electrically insulating layer 320 can help protect the second components 310, 312, e.g., facing the channel 115, from detrimental effects of tribological charge in the channel 115. In some embodiments, the layer 320 preferably is composed of a material that has a high thermal conductivity. Non-limiting example materials of the layer 320 include diamond or other material with similar low electrical conductivity, but, high thermal conductivity. Other non-limiting example materials of the layer 320 with low electrical conductivity and low thermal conductivity include silicon dioxide or similar materials.

As further illustrated in FIG. 3B the second integrated circuit 305 can also include an electrically conductive layer 122 located on at least one wall 124 of the channel 115 (e.g., interior channel wall of the second substrate 307) and some embodiments, located on at least a portion of the electrically insulating layer 320. The electrically conductive layer 122 can electrically connect (e.g., by one or more low resistance ground-path structures 130) the dielectric fluid 117 in the channel 115 to a ground body 126 adjacent to the second substrate 307. Based on the disclosure one skilled in the pertinent art would appreciate how the second circuit could have any of the configurations of the electrically conductive layer, ground path structures, and ground body as discussed above in the context of FIGS. 1-3.

Based upon the disclosure one skilled in the pertinent art would appreciate how more than two integrated circuits 105, 305 could be stacked together with at least one channel 115 and one grounding system 120 being located between adjacent pairs of integrated circuits 105, 305.

One skilled in the pertinent art would appreciate how, in some embodiments, the two or more integrated circuits 105, 305 on different substrates 107, 307 can be interconnected with each other to form to form a three dimensional multi-core central processing unit.

Returning to FIG. 1A, as illustrated, in some embodiments, the apparatus 100 further comprises a pump 170 connected to move a liquid 117 through the channel 115. As also illustrated in FIG. 1A in some embodiments, the apparatus 100 further comprises a heat exchanger 175 configured to receive fluid 117 from the channel 115 and being located external to the integrated circuit 105. In some embodiments, a pump 170 is connected to move the fluid 117 through the channel 115 and from the channel 115 to the heat exchanger 175, and in some cases, back to the pump 170 to form a closed loop.

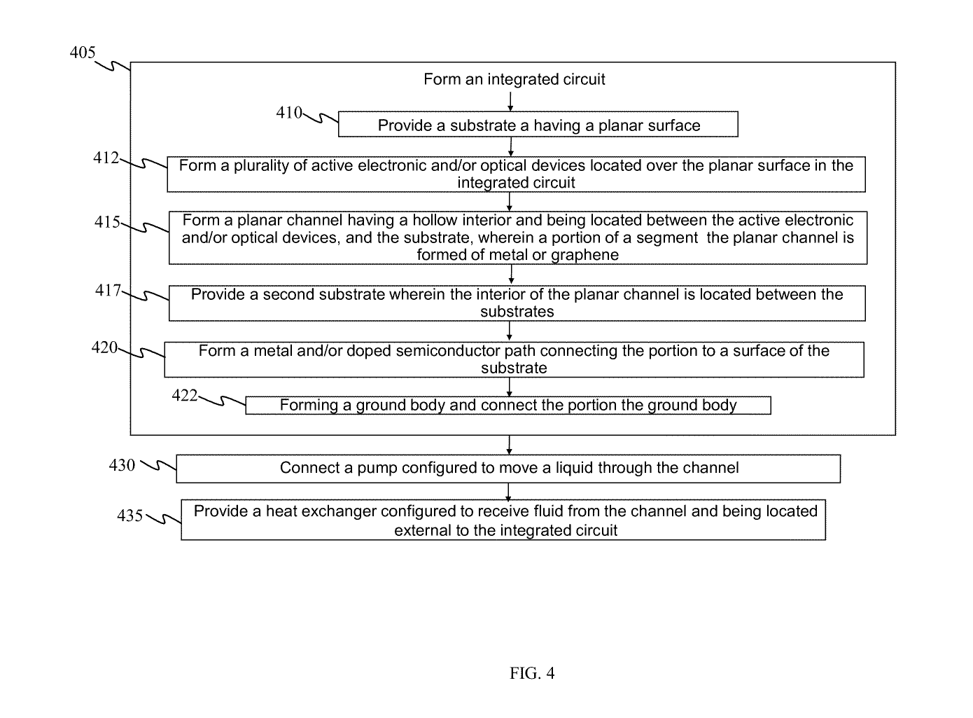

Another embodiment of the disclosure is a method. FIG. 4 presents a flow diagram of a various aspects of a method. With continuing reference to FIG. 1A the method comprises a step 405 of forming an integrated circuit 105. Forming the integrated circuit 105 includes a step 410 of providing a substrate 107a having a planar surface 108a, a step 412 of forming a plurality of active electronic and/or optical devices 110 located over the planar surface 108 in the integrated circuit 105, and, a step 415 forming a planar channel 115 having a hollow interior 116 and being located between the active electronic and/or optical devices 110, and the substrate 107, wherein a portion 122 of a segment 116 the planar channel 115 is formed of metal or graphene.

In some embodiments, forming the integrated circuit 105 (step 405) further includes a step 417 of providing a second substrate 107a wherein the interior 116 of the planar channel 115 is located between the substrates 107a, 107b.

In some embodiments, forming the integrated circuit 105 (step 405) further includes a step 420 of forming a metal and/or doped semiconductor path 130 connecting the portion to a surface (e.g., surface 108a or 108b) of the substrate (e.g., substrate 107a or 107b).

In some embodiments, forming the integrated circuit 105 (step 405) further includes a step 422 of forming a ground body 126 and connecting the portion 122 to the ground body 126.

Some embodiments of the method further include a step 430 of connecting a pump 170 configured to move a liquid 117 through the channel 115. Some embodiments of the method further include a step 435 of providing a heat exchanger 175 configured to receive fluid 117 from the channel 115 and being located external to the integrated circuit 105. In some cases, connecting the pump 170 in step 430 includes moving the fluid 117 through the channel 115 and from the channel 115 to the heat exchanger 175.

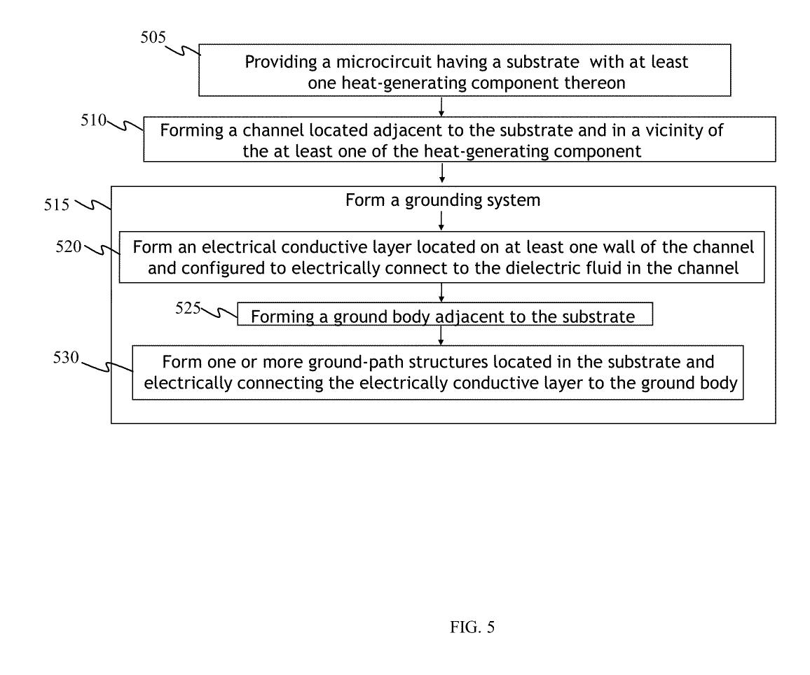

Another embodiment of a method of manufacturing an apparatus is illustrated in the flow diagram presented in FIG. 5. With continuing reference to FIGS. 1B-3 throughout, embodiments of the method can comprise a step 505 of providing an integrated circuit 105 having a substrate 105 with at least one heat-generating active device component (e.g., at least one of components 110, 112) thereon. Embodiments of the method can comprise a step 510 of forming a channel 115 located adjacent to the substrate 107 and in a vicinity of the at least one of the heat-generating active device component 110, 112. The channel 115 is configured to carry a dielectric fluid 117 there-through.

Embodiments of the method of manufacturing the apparatus 100 can comprise a step 515 of forming a grounding system 120. Forming the grounding system 120 (step 515) can include a step 520 of forming an electrical conductive layer 122 located on at least one wall 124 of the channel 115 and configured to electrically connect to the dielectric fluid 117 in the channel 115. Forming the grounding systems 120 (step 515) can include a step 525 of forming a low-resistance ground body 126 adjacent to the substrate 107. Forming the grounding systems 120 (step 515) can include a step 530 of forming one or more low resistance ground-path structures (e.g., one or more of structure 130 or structure 132) located in the substrate 107 and electrically connecting the electrically conductive layer 122 to the ground body 126.

In some embodiments of the method of manufacturing the apparatus 100, forming the channel (step 510) can includes forming a gap between a first portion 160 of the substrate 107 and a second portion 162 of the substrate 107, such that the gap can include or be the channel 115 (see e.g., FIG. 1B). In such embodiments, where the first and second portions 160, 162 are part of a single substrate 107, the channel 115 can be within the substrate 107 and adjacent to the substrate 107. One skilled in the pertinent arts would be familiar with procedures such as etching or laser drill processes, to form a gap. In some embodiments, forming the channel (step 510) can include coupling (e.g., via flip chip bonding, fusing other chip bonding procedures familiar to those skilled in the pertinent art) a first substrate (e.g., substrate 107 or first portion 160) to a second substrate (e.g., second substrate 307 or second portion 162) so as to provide a gap between the substrates 107, 307 that can be or include the channel 115. As discussed in the context of FIG. 3A, each of the substrates can be part of a integrated circuit (e.g., circuit 105, 305) having heat-generating components 110, 112 thereon.

In some embodiments, forming the electrically conductive layer 122 (step 520) includes forming a metal or graphene or carbon nanotube or other material layer on one side 140 of the substrate (e.g., substrate portion 162), e.g. prior to coupling two substrates 107, 307 together as part of step 510. One skilled in the art would be familiar with material deposition procedures (e.g., electroless or electrolytic deposition, chemical or physical deposition) to form the layer 122

In some embodiments, forming the electrically conductive layer (step 520) include doping a portion 148 of one side 140 of the substrate 107 with N-type or P-type dopants. One skilled in the pertinent art would be familiar with dopant implantation and thermal annealing procedures to form the doped portion 148.

In some embodiments, forming the electrically conductive layer 122 (step 520) includes embedding the layer in the side 140 of the substrate 107. For instance, in some embodiments a trench 142 can be formed in the substrate (e.g., by lithographic patterning and etching procedures) and a material layer 122 deposited in the trench 142.

In some embodiments, forming the ground body 126 adjacent to the substrate 107 (step 525) includes depositing a conductive material layer (e.g., a metal or graphene layer or carbon nanotube dispersion layer) at or near a top-side 215 or a bottom side 220 of the substrate 107 (FIG. 2). In some embodiments, for example, the low resistance ground body (e.g., one or both of ground bodies 126, 210) can be formed on an interior substrate portion 107′ with subsequent further deposition of the substrate material on the ground body. In some embodiments, for example, the ground body (e.g., one or both of ground body 126, 210) can be formed by implanting dopant into the substrate 107 followed by thermal annealing to form the ground body 126.

In some embodiments, forming the low-resistance ground-path structure 130, 132 (step 530) includes forming a metal-containing via that passes through at least a portion of a thickness 134 of the substrate 107 (FIG. 1B). One skilled in the pertinent arts would be familiar with procedures (e.g., lithographic patterning and etching procedures and via fill procedures) to form a via or through-substrate-via as part of forming the ground-path structure in step 530. In some embodiments, forming the ground-path structure 150 (step 530) includes implanting dopants (e.g., N-type or P-type dopants) into a portion 148 of the substrate 107.

Although the present disclosure has been described in detail, those skilled in the art should understand that they can make various changes, substitutions and alterations herein without departing from the scope of the invention.

1. An apparatus, comprising:
an integrated circuit, the integrated circuit comprising:
a substrate having a planar surface;
a plurality of active electronic and/or optical devices located over the planar surface in the integrated circuit; and
a planar channel having a hollow interior and being located between the active electronic and/or optical devices, and the substrate; and
wherein a portion of a segment of the planar channel is formed of metal or graphene.

2. The apparatus of claim 1, wherein the portion forms a top surface or a bottom surface of the segment of the planar channel.

3. The apparatus of claim 1, wherein the portion forms between 25 percent and 75 percent of a surface of a cross section of the segment of the planar channel.

4. The apparatus of claim 1, wherein the portion is connected by a metal and/or doped semiconductor path to a surface of the substrate.

5. The apparatus of claim 1, wherein the integrated circuit includes a second substrate and the interior of the planar channel is located between the substrates.

6. The apparatus of claim 1, wherein the portion is connected to a ground body of the integrated circuit.

7. The apparatus of claim 1, further comprising a pump connected to move a liquid through the channel.

8. The apparatus of claim 1, further comprising a heat exchanger configured to receive fluid from the channel and being located external to the integrated circuit.

9. The apparatus of claim 8, further comprising a pump connected to move the fluid through the channel and from the channel to the heat exchanger.

10-16. (canceled)

17. An apparatus, comprising:
an integrated circuit having a substrate with at least one heat-generating component thereon;
a channel located adjacent to the substrate and in a vicinity of the at least one of the heat-generating component, wherein the channel is configured to carry a dielectric fluid there-through; and
a grounding system, including:
an electrically conductive layer located on at least one wall of the channel and configured to electrically connect to the dielectric fluid in the channel;
a ground body adjacent to the substrate, and
one or more ground-path structures located in the substrate and electrically connecting the electrically conductive layer to the ground body.

18. The apparatus of claim 17, wherein at least a segment of the electrically conductive layer located on the at least one wall of the channel and configured to electrically connect to the dielectric fluid in the channel is formed of graphene.

19. The apparatus of claim 17, wherein at least a portion of the ground-path structure includes a structure that traverses the channel and contacts the he dielectric fluid in the channel.

20. The apparatus of claim 19, wherein the structure traversing the channel is a via structure that passes through the substrate and contacts the ground body.
